(19) United States
(12) Patent Application Publication
(10) Pub. No.: US 2004/0187779 A1
(43) Pub. Date: Sep. 30, 2004

(54) Thin film deposition reactor

(76) Inventors: Young Hoon Park, Pyungtaek-city (KR); Keun Jae Yoo, Pyungtaek-city (KR); Sang Kwon Park, Pyungtaek-city (KR); Byung Chul Cho, Pyungtaek-city (KR); Seoung Wook Lee, Pyungtaek-city (KR); Hong Joo Lim, Pyungtaek-city (KR); Sang Kyu Lee, Pyungtaek-city (KR); Jang Ho Bae, Pyungtaek-city (KR)

Correspondence Address: Cantor Colburn LLP, 55 Griffin South Road, Bloomfield, CT, 06002, US

(21) Appl. No.: 10/800,242

(22) Filed: Mar. 12, 2004

(30) Foreign Application Priority Data
Mar. 27, 2003 (KR) 2003-19135

(51) Int. Cl. C23C 16/00

(52) U.S. Cl. 118/715

(57) ABSTRACT

Provided is a thin film deposition reactor. The reactor includes a reactor block including a wafer block on which a wafer is mounted; a top lid for covering and sealing the reactor block; a showerhead disposed under the top lid and connected to an RF power supply unit, the showerhead having first nozzles and second nozzles that are not combined with each other; a showerhead isolation assembly having a plurality of gas curtain holes for forming a gas curtain around the wafer block, the showerhead isolation assembly for isolating the top lid from the showerhead; a top lid isolation flow line disposed on the top lid, the top lid isolation flow line having a first flow line and a second flow line that are connected to the first nozzles and the second nozzles, respectively, and are each bent at a right angle at least once.

This application claims the priority of Korean Patent Application No. 2003-19135, filed on Mar. 27, 2003, in the Korean Intellectual Property Office, the disclosure of which is incorporated herein by reference in its entirety.

### BACKGROUND OF THE INVENTION

1. Field of the Invention

The present invention relates to a thin film deposition reactor for depositing thin films using plasma.

2. Description of the Related Art

A plasma enhanced chemical vapor deposition (PECVD) apparatus is used to cause a chemical (substitution) reaction between two reaction gases and grow a desired thin film on a wafer. A pyrolysis energy required for a substitution reaction is supplied from a heater in a wafer block on which the wafer is mounted. However, if the pyrolysis energy supplied from the heater is not sufficient to form a thin film, a radio frequency (RF) power is applied to a deposition space of a reactor so as to induce activation of a reaction gas. This facilitates deposition of the thin film on the wafer.

A conventional method of depositing a thin film involves depositing a Ti thin film on a wafer using an H₂ gas and a TiCl₄ gas. Generally, when a Ti thin film is deposited on a wafer, a heater is maintained at a temperature of about 60° C. and RF power of at least several hundred watts is applied to a metal showerhead such that plasma is generated. Theoretically, without using plasma, it is possible to deposit a Ti thin film by raising the temperature of a heater to a very high temperature, but this method is impractical and inefficient.

Also, plasma can be used during a cleaning process after depositing the thin film. After an inside of a reactor is heated, the deposited thin film can be dry cleaned using an erosive gas containing halogen elements, such as F, Cl, and Br. However, the deposited thin film, which is formed of Al₂O₃, HfO₂, or ZrO₃, cannot be sufficiently dry cleaned in this manner. Thus, to perform reliable dry cleaning, plasma must be generated in the reactor.

### SUMMARY OF THE INVENTION

The present invention provides a thin film deposition reactor that enables efficient deposition and dry cleaning of thin films using plasma.

According to an aspect of the present invention, there is provided a thin film deposition reactor comprising a reactor block including a wafer block on which a wafer is mounted. A top lid covers and seals the reactor block. A showerhead is disposed under the top lid, connected to an RF power supply unit, and has first nozzles and second nozzles that are not combined with each other. A showerhead isolation assembly has a plurality of gas curtain holes for forming a gas curtain around the wafer block. The showerhead isolation assembly isolates the top lid from the showerhead. A top lid isolation flow line is disposed on the top lid and has a first flow line and a second flow line, which are connected to the first nozzles and the second nozzles, respectively, and are each bent at a right angle at least once.

The showerhead isolation assembly can comprise a first showerhead assembly and a second showerhead assembly. The first showerhead assembly can be disposed between the top lid and the showerhead, and the second showerhead assembly can enclose an outer circumference of the showerhead and have a plurality of gas curtain holes that are connected to a third flow line formed in the top lid.

The thin film deposition reactor can further comprise a reactor block isolation flow line mounted on the reactor block. The reactor block isolation flow line can have first, second, and third reactor flow lines, which are connected to the first, second, and third flow lines, respectively, and are each bent at a right angle at least once.

The thin film deposition reactor can further comprise a circular pumping baffle that protects the inner surface of the reactor from erosive reaction gases and, together with the showerhead and the wafer block, defines a deposition space. Herein, the pumping baffle can comprise a vertical portion and a horizontal portion. The vertical portion can be disposed in an upper portion of the reactor block, and the horizontal portion can be disposed at a lower portion of the reactor block and have pumping holes.

According another aspect of the present invention, there is provided a thin film deposition reactor comprising a reactor block including a wafer block on which a wafer is mounted. A top lid covers and seals the reactor block and has a plurality of gas curtain holes for forming a gas curtain around the wafer block. A showerhead is disposed under the top lid, connected to an RF power supply unit, and has first nozzles and second nozzles that are not combined with each other. A showerhead isolation assembly isolates the top lid from the showerhead. A top lid isolation flow line is disposed on the top lid and has a first flow line and a second flow line, which are connected to the first nozzles and the second nozzles, respectively, and are each bent at a right angle at least once.

The showerhead isolation assembly can comprise a first showerhead assembly and a second showerhead assembly. The first showerhead assembly can be disposed between the top lid and the showerhead, and the second showerhead assembly can enclose an outer circumference of the showerhead.

The thin film deposition reactor can further comprise a reactor block isolation flow line mounted on the reactor block. The reactor block isolation flow line can have first, second, and third reactor flow lines, which are connected to the first, second, and third flow lines, respectively, and are each bent at a right angle at least once.

The gas curtain holes can be connected to any flow line in the reactor block isolation flow line through a circular channel and the third flow line formed in the top lid.

The thin film deposition reactor can further comprise a circular pumping baffle that protects the inner surface of the reactor from erosive reaction gases and, together with the showerhead and the wafer block, defines a deposition space. Herein, the pumping baffle can comprise a vertical portion and a horizontal portion. The vertical portion can be disposed in an upper portion of the reactor block, and the horizontal portion can be disposed at a lower portion of the reactor block and have pumping holes.

### BRIEF DESCRIPTION OF THE DRAWINGS

The above object and advantages of the present invention will become more apparent by describing in detail exemplary embodiments thereof with reference to the attached drawings in which:

FIG. 1 is a cross-sectional view of a thin film deposition reactor according to an embodiment of the present invention;

FIG. 2 is a perspective view of a top lid and a top lid isolation flow line of FIG. 1;

FIG. 3 is a perspective view of first and second nozzles formed in a bottom surface of a showerhead of FIG. 1;

FIG. 4 is a perspective view of the showerhead and a showerhead isolation assembly of FIG. 1;

FIG. 5 is a perspective view of a reactor block isolation flow line of FIG. 1;

FIG. 6 is a cross-sectional view of a thin film deposition reactor according to another embodiment of the present invention;

FIG. 7 is a perspective view of a top lid of FIG. 6; and

FIG. 8 is a perspective view of a showerhead and a showerhead isolation assembly of FIG. 6.

### DETAILED DESCRIPTION OF THE INVENTION

The present invention will now be described more fully with reference to the accompanying drawings, in which exemplary embodiments of the invention are shown.

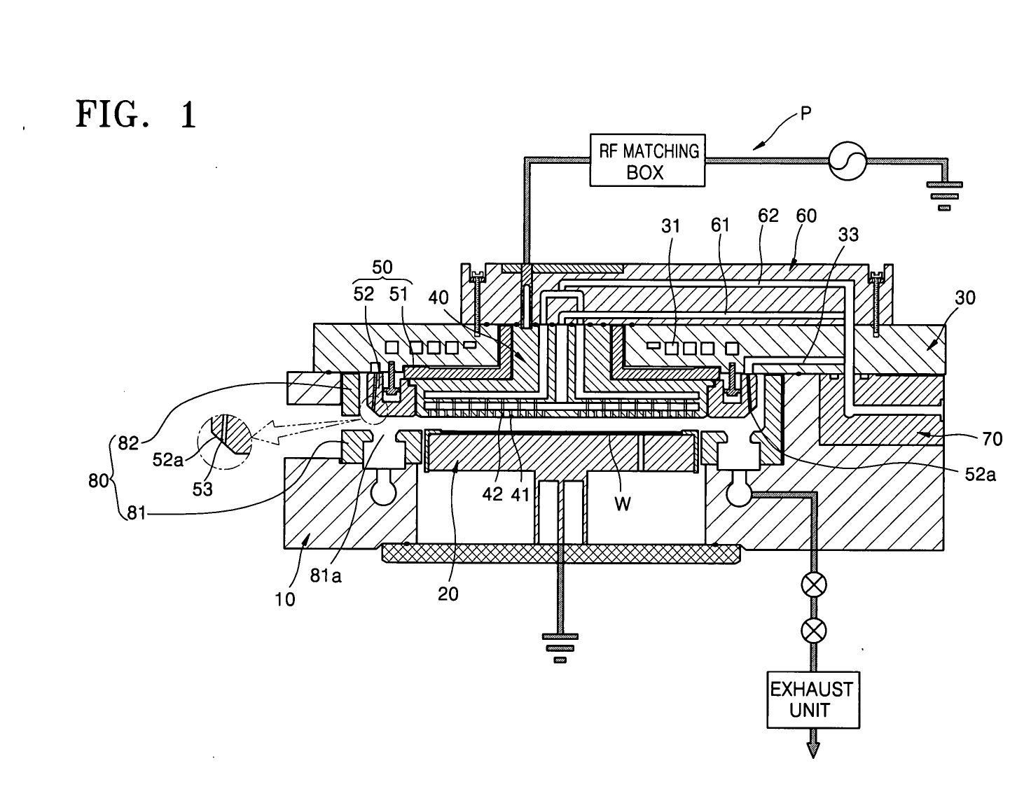

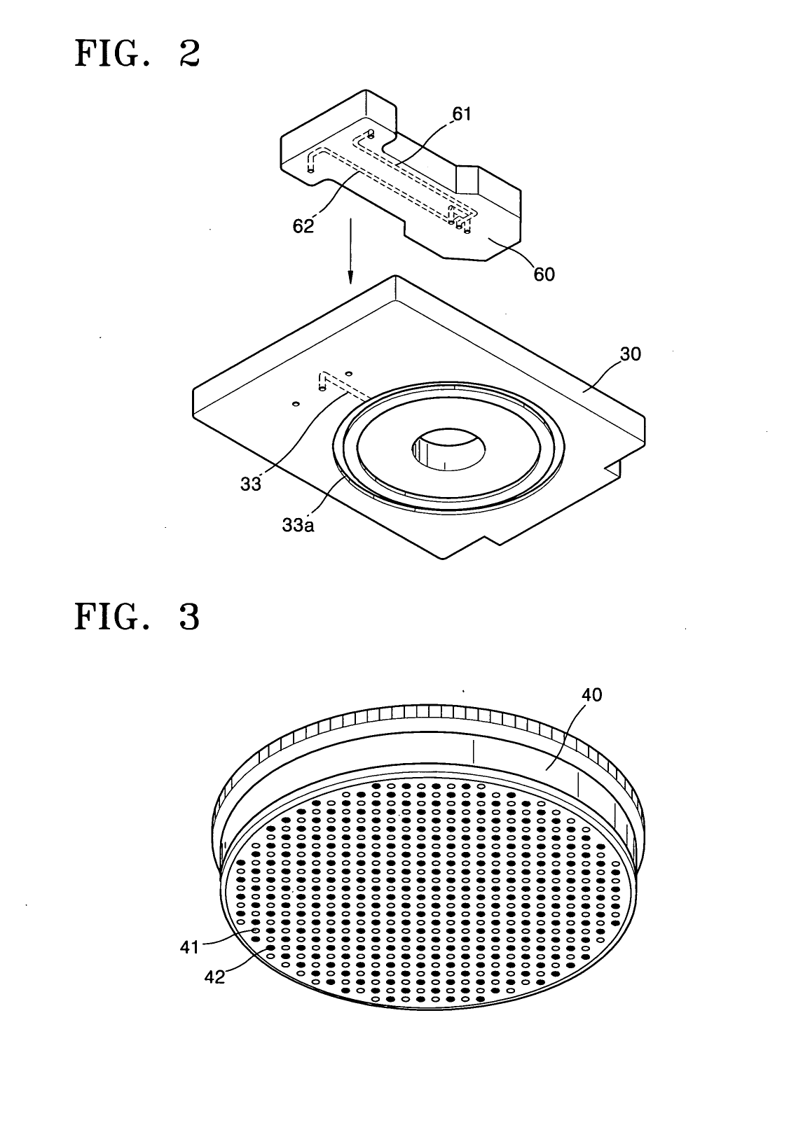

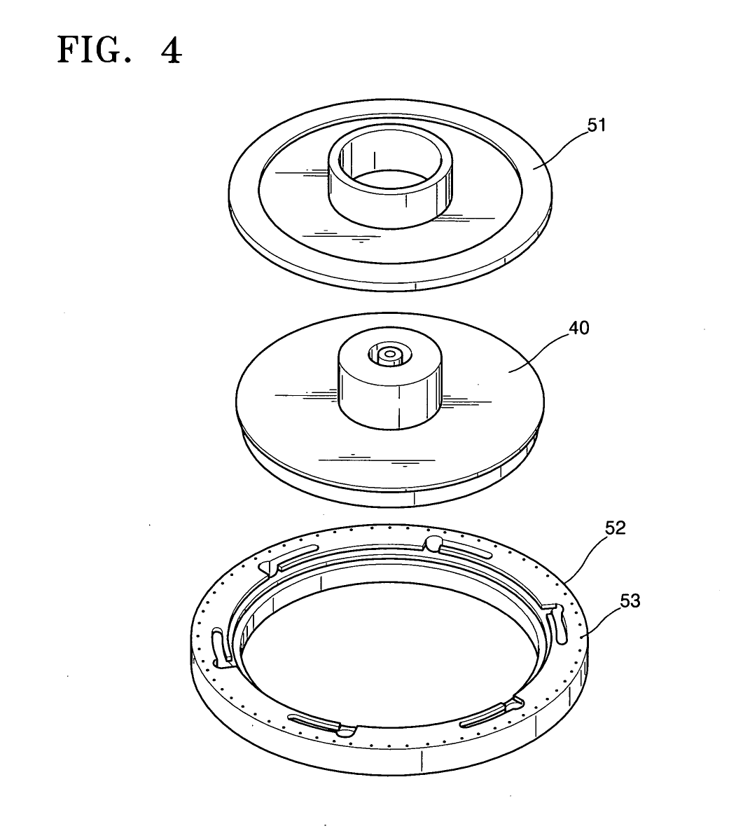

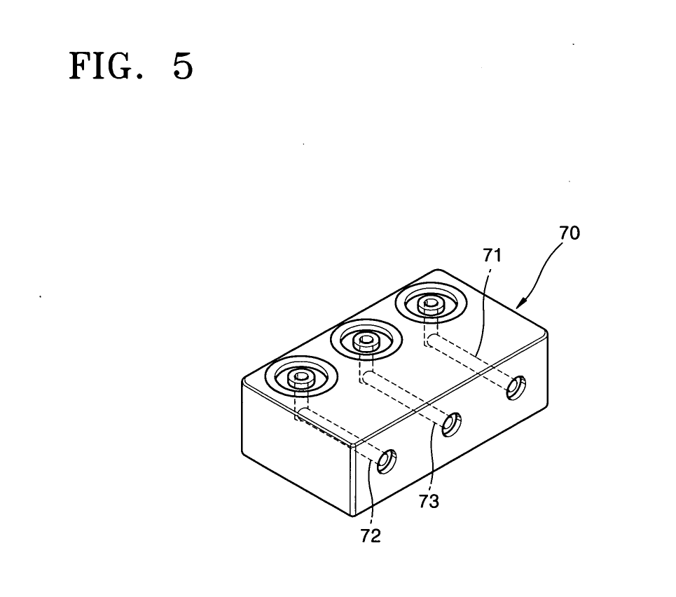

FIG. 1 is a cross-sectional view of a thin film deposition reactor according to an embodiment of the present invention, FIG. 2 is a perspective view of a top lid and a top lid isolation flow line of FIG. 1, FIG. 3 is a perspective view of first and second nozzles formed in a bottom surface of a showerhead of FIG. 1, FIG. 4 is a perspective view of the showerhead and a showerhead isolation assembly of FIG. 1, and FIG. 5 is a perspective view of a reactor block isolation flow line of FIG. 1.

Referring to FIGS. 1 through 5, a thin film deposition reactor of the present embodiment comprises a reactor block 10, a top lid 30, a showerhead 40, a showerhead isolation assembly 50, a top lid isolation flow line 60, a reactor block isolation flow line 70, and a pumping baffle 80. The reactor block 10 includes a wafer block 20 on which a wafer W is mounted, and the top lid 30 covers and seals the reactor block 10. The showerhead 40 is disposed under the top lid 30 and connected to an RF power supply unit P. The showerhead 40 has first nozzles 41 and second nozzles 42, which are not combined with each other. The showerhead isolation assembly 50 isolates the top lid 30 from the showerhead 40 and has a plurality of gas curtain holes 53, which form a gas curtain around the wafer block 20. The top lid isolation flow line 60 is disposed on the top lid 30 and has a first flow line 61 and a second flow line 62, which are connected to the first nozzles 41 and the second nozzles 42, respectively, and are each bent at a right angle at least once. The reactor block isolation flow line 70 is mounted on the reactor block 10 and has first, second, and third reactor flow lines 71, 72 and 73, which are connected to the first and second flow lines 61 and 62, and gas curtain holes 53, respectively. The first, second, and third reactor flow lines 71, 72, and 73 are each bent at a right angle at least once. The pumping baffle 80 is disposed between the reactor block 10 and the wafer block 20 and has pumping holes 81 a to exhaust gases from the reactor.

A coolant flow line 31 is formed in the top lid 30. A coolant in the coolant flow line 31 prevents the showerhead 40 from overheating due to radiation generated by the wafer block 20 and controls the temperature of the showerhead 40. Water, oil, or air may be used as the coolant.

A circular channel 33a is formed in a bottom surface of the top lid 30 and connected to the gas curtain holes 53 and a third flow line 33, as shown in FIG. 2.

The showerhead 40 is formed of a metallic material such as nickel, aluminum, Hasfelloy, or Inconel. If the showerhead 40 is formed of aluminum, an erosion-resistant layer containing tungsten may be coated on an outer surface of the showerhead 40. The first nozzles 41 and the second nozzles 42 are formed at regular intervals in the bottom surface of the showerhead 40, as shown in FIG. 3. In FIG. 3, for clarity of explanation, the first nozzles 41 are illustrated with white circles, and the second nozzles 42 are illustrated with dark circles.

The showerhead isolation assembly 50 is formed of an insulating material, such as ceramic, so as to electrically isolate the showerhead 40 from the top lid 30. The showerhead isolation assembly 50 comprises a first showerhead isolation assembly 51 and a second showerhead isolation assembly 52. The first showerhead isolation assembly 51 is interposed between the top lid 30 and the showerhead 40, and the second showerhead isolation assembly 52 encloses an outer circumference of the showerhead 40 and has the gas curtain holes 53. The second showerhead isolation assembly 52 has an inclined surface 52a opposite to an inner surface of the reactor block 20. The gas curtain holes 53 are formed in the inclined surface 52a, connected to the circular channel 33a of the top lid 30, and also connected to the third flow line 33, as shown in FIG. 1. The gas curtain holes 53 form a gas curtain around an inner sidewall of the reactor, thus preventing deposition of thin films on the inner sidewall of the reactor.

The top lid isolation flow line 60 is formed of an insulating material, such as ceramic, so as to prevent plasma from leaking in a main gas line (not shown), and is additionally combined with the top lid 30, as shown in FIG. 2. When high-frequency RF power is supplied to the showerhead 40, plasma is generated and flows through the first and second flow lines 61 and 62 and may be propagated to a reaction gas line (not shown) that supplies reaction gases or MFCs or other electronic control circuits of various flow rate control systems. Thus, to prevent leakage of plasma, it is desirable to increase lengths of the first and second flow lines 61 and 62 or bend each of them at right angles several times. In the present embodiment, the top lid insulation flow line 60 is formed of an insulating material to prevent the leakage of plasma, and the first and second flow lines 61 and 62 are each bent twice at right angles to prevent propagation of the plasma through the first and second flow lines 61 and 62.

The reactor block insulation flow line 70 is also formed of an insulating material such as ceramic to prevent leakage of plasma, and is additionally combined with the reactor block 10 as shown in FIG. 1. The reactor block insulation flow line 70 has first, second, and third reactor flow lines 71, 72, and 73, which are connected to the first, second, and third flow lines 61, 62, and 33, respectively, and are each bent at a right angle to prevent the leakage of plasma. Although the first, second, and third reactor flow lines 71, 72, and 73 are each bent at a right angle only once in the present embodiment, they can be bent at right angles several times more than once.

The pumping baffle 80 protects an inner sidewall of the reactor from erosive reaction gases and, together with the showerhead 40 and the wafer block 20, defines a deposition space. The pumping baffle 80 has a circular shape and comprises a vertical portion 82 and a horizontal portion 81. The vertical portion 82 is disposed in an upper portion of the reactor block 10, and the horizontal portion 81 is disposed in a lower portion of the reactor block 10 and has pumping holes 81a. The pumping baffle 80 is formed of nickel, aluminium, Hasfelloy, Inconel, or ceramic. If the pumping baffle 80 is formed of aluminium, an erosion-resistant layer containing tungsten may be coated on the pumping baffle 80.

The operation of the above-described thin film deposition will now be described.

A wafer W is mounted on a wafer block 20. Then, the wafer W is preheated for a predetermined amount of time by spraying a reaction gas and/or inert gas through first, second, and third flow lines 61, 62, and 33 to a showerhead 40.

While the reaction gas is being sprayed on the wafer W, RF power is applied to the showerhead. The RF power excites the reaction gas to generate plasma, thus facilitating pyrolysis substitution on the wafer W. This leads to high-speed formation of a thin film of a high degree of purity on the wafer W. The RF power typically has a frequency of 13.65 MHz.

The reaction gas can be fed through the first and second flow lines 61 and 62 into the reactor using chemical vapor deposition (CVD) or atomic layer deposition (ALD). To accelerate the deposition of a thin film, the CVD is used and, if necessary, plasma can be generated. Alternatively, plasma can be generated during a post-processing process instead of the deposition process. A reaction gas and/or inert gas such as H₂, NH₃, N₂, or Ar can be sprayed during the post-processing process.

Also, the plasma can be used during dry cleaning. In many cases, only heat energy is used for dry cleaning. However, when a thin film is formed using monatomic oxides such as Al₂O₃, ZrO₂, or HfO₂, the inner space of the reactor cannot be effectively dry cleaned by only using a conventional erosive gas containing halogen elements (F, Cl, or Br) and heat energy. To perform reliable dry cleaning while spraying the erosive gas in the reactor, RF power is applied to the reactor so as to generate plasma. In this case, the dry cleaning is mainly performed by physical collisions between the erosive gas and the surface of the reactor. Therefore, as an atomic mass of gaseous molecules for dry cleaning increases, the efficiency of the dry cleaning improves.

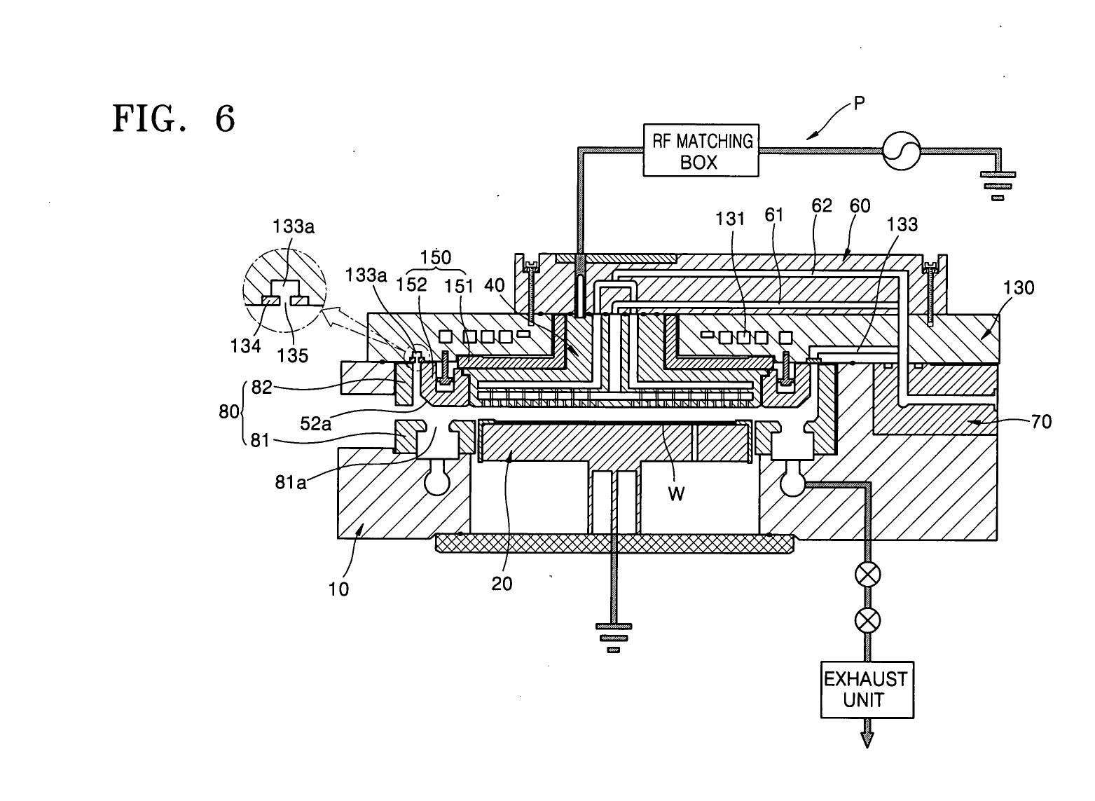

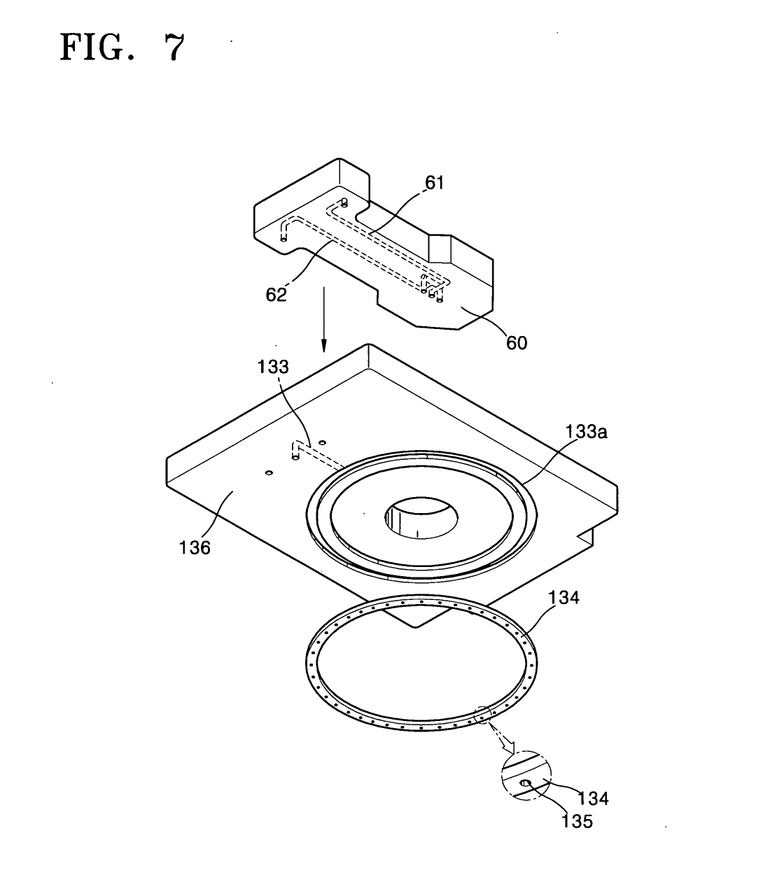

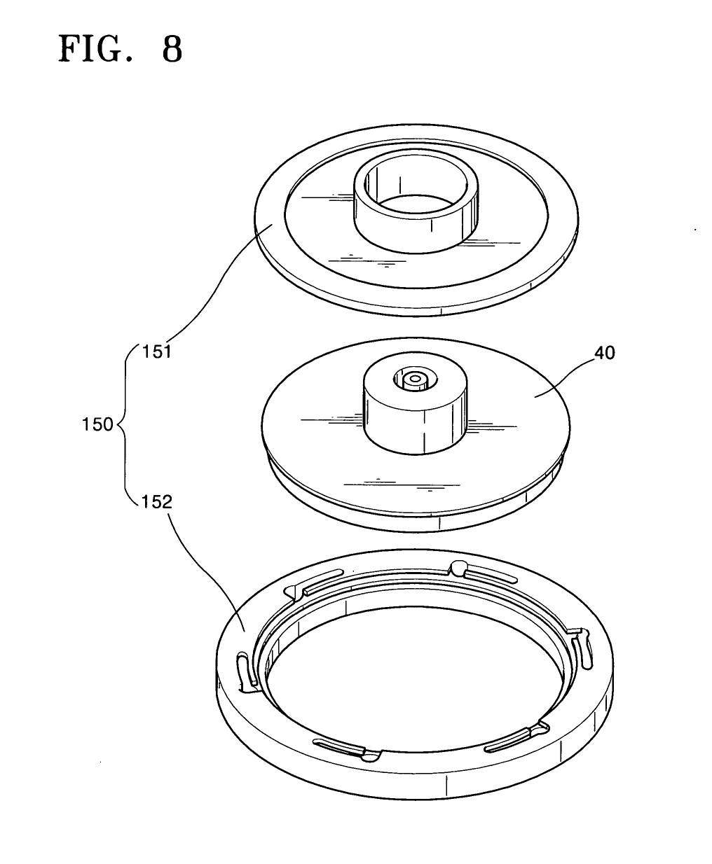

FIG. 6 is a cross-sectional view of a thin film deposition reactor according to another embodiment of the present invention, FIG. 7 is a partial perspective view of a top lid shown in FIG. 6, and FIG. 8 is a partial perspective view of a showerhead and a showerhead isolation assembly shown in FIG. 6. In the present embodiment, the same numerals are used to denote the same elements as in the first embodiment.

The thin film deposition reactor of the present embodiment comprises a reactor block 10, a top lid 130, a shower head 40, a showerhead isolation assembly 150, a top lid isolation flow line 60, a reactor block insulation flow line 70, and a pumping baffle 80. The reactor block 10 includes a wafer block 20 on which a wafer W is mounted. The top lid 130 covers and seals the reactor block 10 and has a plurality of gas curtain holes 135, which form a gas curtain around the wafer block 20, and a third flow line 133 connected to the gas curtain holes 135. The showerhead 40 is disposed under the top lid 130, connected to an RF power supply unit P, and has first nozzles 41 and second nozzles 42, which are not combined with each other. The showerhead isolation assembly 150 isolates the top lid 130 from the showerhead 40. The top lid isolation flow line 60 is disposed on the top lid 130 and has a first flow line 61 and a second flow line 62, which are connected to the first nozzles 41 and the second nozzles 42, respectively, and are each bent at a right angle at least once. The reactor block isolation flow line 70 is mounted on the reactor block 10 and has first, second, and third reactor flow lines 71, 72, and 73, which are connected to the first and second flow lines 61 and 62, and gas curtain holes 135, respectively, and are each bent at a right angle at least once. The pumping baffle 80 is disposed between the reactor block 10 and the wafer block 20 and has pumping holes for exhausting inner gases.

A coolant flow line 131 is formed in the top lid 130. Since the coolant flow line 131 is equivalent to that of the first embodiment, a description thereof will not be repeated here.

As shown in FIG. 7, a circular channel 133a is formed in the top lid 130. The circular channel 133a is connected to any flow line. The circular channel 133a is connected to a third flow line 133 in the present embodiment. A cover member 134 having a plurality of gas curtain holes 135 is disposed in the circular channel 133a. The gas curtain holes 135 are formed in the cover member 134 at regular intervals. The third flow line 133 is connected to the third reactor flow line 73 of the reactor block isolation block 70. Thus, a gas flows through the third reactor flow line 73 and the third flow line 133 and is sprayed via the circular channel 133a and the gas curtain holes 135. The gas curtain holes 135 form a gas curtain around the inner wall of the reactor, thus minimizing deposition of a thin film on the inner wall of the reactor.

Since the showerhead 40 is equivalent to that of the first embodiment, a description thereof will not be repeated here.

The showerhead isolation assembly 150 is formed of an insulating material that electrically isolates the showerhead 40 from the top lid 130. As shown in FIG. 8, the showerhead isolation assembly 150 includes a first showerhead assembly 151 and a second showerhead assembly 152. The first showerhead assembly 151 is disposed between the top lid 130 and the showerhead 40, and the second showerhead assembly 152 encloses an outer circumference of the showerhead 40.

Since the top lid isolation flow line 60, the reactor block isolation flow line 70, and the pumping baffle 80 are the same as those of the first embodiment, descriptions thereof will not be repeated here.

As described above, in the thin film deposition reactor of the present invention, a thin film can be deposited using plasma more efficiently. Also, when a thin film is formed using Al₂O₃, HfO₂, or ZrO₂, the efficiency of dry cleaning is improved by generating plasma.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A thin film deposition reactor comprising:
a reactor block comprising a wafer block on which a wafer is mounted;
a top lid for covering and sealing the reactor block;
a showerhead disposed under the top lid and connected to an RF power supply unit, the showerhead having first nozzles and second nozzles that are not combined with each other;
a showerhead isolation assembly having a plurality of gas curtain holes for forming a gas curtain around the wafer block, the showerhead isolation assembly for isolating the top lid from the showerhead;
a top lid isolation flow line disposed on the top lid, the top lid isolation flow line having a first flow line and a second flow line, which are connected to the first nozzles and the second nozzles, respectively, and are each bent at a right angle at least once.

2. The reactor of claim 1, wherein the showerhead isolation assembly comprises:
a first showerhead assembly disposed between the top lid and the showerhead; and
a second showerhead assembly which encloses an outer circumference of the showerhead and has a plurality of gas curtain holes that are connected to a third flow line formed in the top lid.

3. The reactor of claim 2, further comprising a reactor block isolation flow line mounted on the reactor block, the reactor block isolation flow line having first, second, and third reactor flow lines, which are connected to the first, second, and third flow lines, respectively, and are each bent at a right angle at least once.

4. The reactor of claim 1, further comprising a circular pumping baffle that protects the inner surface of the reactor from erosive reaction gases and, together with the showerhead and the wafer block, defines a deposition space,
wherein the pumping baffle comprises a vertical portion disposed in an upper portion of the reactor block and a horizontal portion disposed in a lower portion of the reactor block and having pumping holes.

5. A thin film deposition reactor comprising:
a reactor block comprising a wafer block on which a wafer is mounted;
a top lid for covering and sealing the reactor block, the top lid having a plurality of gas curtain holes for forming a gas curtain around the wafer block and a third flow line connected to the gas curtain holes;
a showerhead disposed under the top lid and connected to an RF power supply unit, the showerhead having first nozzles and second nozzles that are not combined with each other and;
a showerhead isolation assembly for isolating the top lid from the showerhead;
a top lid isolation flow line disposed on the top lid, the top lid isolation flow line having a first flow line and a second flow line, which are connected to the first nozzles and the second nozzles, respectively, and are each bent at a right angle at least once.

6. The reactor of claim 5, wherein the showerhead isolation assembly comprises:
a first showerhead assembly disposed between the top lid and the showerhead; and
a second showerhead assembly that encloses an outer circumference of the showerhead.

7. The reactor of claim 5, further comprising a reactor block isolation flow line mounted on the reactor block, the reactor block isolation flow line having first, second, and third reactor flow lines, which are connected to the first, second, and third flow lines, respectively and are each bent at a right angle at least once.

8. The reactor of claim 5, further comprising a circular pumping baffle that protects the inner surface of the reactor from erosive reaction gases and, together with the showerhead and the wafer block, defines a deposition space,
wherein the pumping baffle comprises a vertical portion disposed in an upper portion of the reactor block and a horizontal portion disposed at a lower portion of the reactor block and having pumping holes.
